(19) United States
(12) Patent Application Publication
(10) Pub. No.: US 2024/0347567 A1
(43) Pub. Date: Oct. 17, 2024

(54) IMAGING DEVICE AND ELECTRONIC APPARATUS

(71) Applicant: SONY SEMICONDUCTOR SOLUTIONS CORPORATION, KANAGAWA (JP)

(72) Inventor: MIZUKI HOYANO, KANAGAWA (JP)

(21) Appl. No.: 18/682,978

(22) PCT Filed: Mar. 18, 2022
(86) PCT No.: PCT/JP2022/012648

§ 371 Date: Feb. 12, 2024

(30) Foreign Application Priority Data
Sep. 10, 2021 (JP) 2021-147996

(51) Int. Cl. H01L 27/146

(52) U.S. Cl. CPC H01L 27/14623; H01L 27/14621; H01L 27/14627; H01L 27/14645

(57) ABSTRACT

An imaging device that makes it possible to achieve a reduction in size in in-plane directions without sacrificing its operation capability is provided. The imaging device includes: a base body; a pixel array unit; a first inter-identical color pixel wall member; and an inter-pixel light shielding film. The pixel array unit is one where a plurality of first color pixels and a plurality of second color pixels are disposed on the base body. The plurality of first color pixels lie adjacent to each other and each include a first color filter and a first photoelectric conversion unit that receives first color light passed through the first color filter and performs photoelectric conversion on the first color light. The plurality of second color pixels lie adjacent to each other and each include a second color filter and a second photoelectric conversion unit that receives second color light passed through the second color filter and performs photoelectric conversion on the second color light. The first inter-identical color pixel wall member is positioned in a gap among the plurality of first color filters, and has a refractive index lower than a refractive index of the first color filter. The inter-pixel light shielding film is positioned in a gap between the plurality of first color pixels and the plurality of second color pixels, and suppresses transmission of light entering the pixel array unit.

### TECHNICAL FIELD

The present disclosure relates to an imaging device that performs photoelectric conversion to capture an image and an electronic apparatus including the imaging device.

### BACKGROUND ART

The present applicant has proposed so far a solid-state imaging device in which a device separator having a refractive index lower than a refractive index of a color filter is provided in a gap between the color filters, respectively, in pixels adjacent to each other (for example, see PTL 1).

### CITATION LIST

### Patent Literature

PTL 1: WO2014/021115

### SUMMARY OF THE INVENTION

By the way, for such an imaging device, a reduction in size in in-plane directions orthogonal to a light-entering direction has been demanded.

Therefore, what is desired is to provide an imaging device that is suitable for a reduction in size in the in-plane directions without sacrificing its operation capability, and an electronic apparatus including such an imaging device.

An imaging device according to one embodiment of the present disclosure includes: a base body; a pixel array unit; a first inter-identical color pixel wall member; and an inter-pixel light shielding film. The pixel array unit is one where a plurality of first color pixels and a plurality of second color pixels are disposed on the base body. The plurality of first color pixels lie adjacent to each other and each include a first color filter and a first photoelectric conversion unit that receives first color light passed through the first color filter and performs photoelectric conversion on the first color light. The plurality of second color pixels lie adjacent to each other and each include a second color filter and a second photoelectric conversion unit that receives second color light passed through the second color filter and performs photoelectric conversion on the second color light. The first inter-identical color pixel wall member is positioned in a gap among a plurality of the first color filters, and has a refractive index lower than a refractive index of the first color filter. The inter-pixel light shielding film is positioned in a gap between the plurality of first color pixels and the plurality of second color pixels, and suppresses light entering and passing through the pixel array unit.

Furthermore, an electronic apparatus according to the one embodiment of the present disclosure is one that includes the imaging device described above.

In the imaging device and the electronic apparatus according to the one embodiment of the present disclosure having the configuration described above, light passing through the first color filter efficiently enters the first photoelectric conversion unit. Furthermore, light entered the first color pixel becomes less likely to leak to the second color pixel, and light entered the second color pixel becomes less likely to leak to the first color pixel.

### BRIEF DESCRIPTION OF DRAWING

FIG. 1 is a block diagram illustrating a configuration example of an imaging device according to one embodiment of the present disclosure.

FIG. 2 is a circuit diagram illustrating a circuit configuration of one sensor pixel in the imaging device illustrated in FIG. 1.

FIG. 3 is a plan view schematically illustrating a plan configuration of a portion of a pixel array unit in the imaging device illustrated in FIG. 1.

FIG. 4A is a first cross-sectional view schematically illustrating a cross-sectional configuration of the pixel array unit illustrated in FIG. 3.

FIG. 4B is a second cross-sectional view schematically illustrating a cross-sectional configuration of the pixel array unit illustrated in FIG. 3.

FIG. 5 is a plan view schematically illustrating a plan configuration of a portion of a pixel array unit serving as a first modification example of the imaging device illustrated in FIG. 1.

FIG. 6A is a first cross-sectional view schematically illustrating a cross-sectional configuration of the pixel array unit illustrated in FIG. 5.

FIG. 6B is a second cross-sectional view schematically illustrating a cross-sectional configuration of the pixel array unit illustrated in FIG. 5.

FIG. 7 is a plan view schematically illustrating a plan configuration of a portion of a pixel array unit serving as a second modification example of the imaging device illustrated in FIG. 1.

FIG. 8A is a first cross-sectional view illustrating, in an enlarged manner, a portion of a pixel array unit serving as a third modification example of the imaging device illustrated in FIG. 1.

FIG. 8B is a second cross-sectional view illustrating, in an enlarged manner, a portion of a pixel array unit serving as the third modification example of the imaging device illustrated in FIG. 1.

FIG. 9 is a schematic view illustrating an entire configuration example of an electronic apparatus including the imaging device according to the one embodiment of the present disclosure.

FIG. 10 is a block diagram depicting an example of schematic configuration of a vehicle control system.

FIG. 11 is a diagram of assistance in explaining an example of installation positions of an outside-vehicle information detecting section and an imaging section.

FIG. 12 is a view depicting an example of a schematic configuration of an endoscopic surgery system.

FIG. 13 is a block diagram depicting an example of a functional configuration of a camera head and a camera control unit (CCU).

FIG. 14 is a plan view schematically illustrating a plan configuration of a portion of a pixel array unit serving as a fourth modification example of the present disclosure.

FIG. 15 is a cross-sectional view schematically illustrating, in an enlarged manner, a cross-sectional configuration of a portion of a pixel array unit serving as a fifth modification example of the present disclosure.

FIG. 16 is a cross-sectional view schematically illustrating, in an enlarged manner, a cross-sectional configuration of a portion of a pixel array unit serving as a sixth modification example of the present disclosure.

FIG. 17 is a cross-sectional view schematically illustrating, in an enlarged manner, a cross-sectional configuration of a portion of a pixel array unit serving as a seventh modification example of the present disclosure.

FIG. 18 is a cross-sectional view schematically illustrating, in an enlarged manner, a cross-sectional configuration of a portion of a pixel array unit serving as an eighth modification example of the present disclosure.

### MODES FOR CARRYING OUT THE INVENTION

In the following, an embodiment of the present disclosure will be described in detail with reference to the drawings. It is to be noted that the description will be given in the following order.
1. One Embodiment

This is an example of a solid-state imaging device provided with an inter-pixel light shielding film between pixels that differ from each other in color.
2. Modification Examples to One Embodiment
3. Application Example to Electronic Apparatus
4. Application Example to Movable Body
5. Practical Example to Endoscopic Surgery System
6. Other Modification Examples

### 1. One Embodiment

### [Configuration of Solid-State Imaging Device 101]

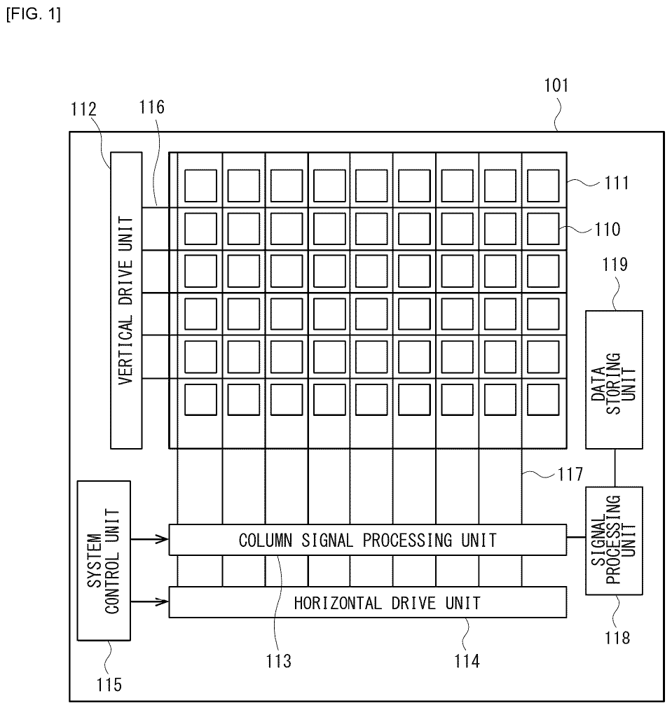

FIG. 1 is a block diagram illustrating a configuration example of functions of a solid-state imaging device 101 according to a first embodiment of the present technique.

The solid-state imaging device 101 is, for example, one called a global shutter style, back surface irradiation type image sensor such as a complementary metal oxide semiconductor (CMOS) image sensor. The solid-state imaging device 101 is one that captures an image by receiving light from an object, performing photoelectric conversion on the light, and generating an image signal.

The global shutter style basically refers to a style of performing global exposure where exposure starts simultaneously on all pixels, and the exposure ends simultaneously on all the pixels. Note herein that all the pixels mean all pixels in a portion appeared on an image, excluding dummy pixels, for example. Furthermore, the global shutter style further includes such a style that, in a case where a time difference or a degree of distortion in an image is sufficiently small to an extent that it does not cause a problem to occur, global exposure is performed in a unit of a plurality of rows (for example, several ten rows), instead of simultaneously performing global exposure on all pixels, and a region on which the global exposure is performed is moved. Furthermore, the global shutter style further includes such a style that global exposure is performed on pixels in a predetermined region, instead of all pixels on a portion appeared in an image.

A back surface irradiation type image sensor refers to an image sensor having a configuration where a photoelectric conversion unit such as a photo diode that receives light from an object and converts the light into an electric signal is provided between a light-receiving surface that receives the light from the object and a wiring layer provided with wiring lines for transistors that drive pixels.

The solid-state imaging device 101 includes, for example, a pixel array unit 111, a vertical drive unit 112, a column signal processing unit 113, a horizontal drive unit 114, a system control unit 115, pixel drive lines 116, vertical signal lines 117, a signal processing unit 118, and a data storing unit 119.

In the solid-state imaging device 101, the pixel array unit 111 is formed on a semiconductor substrate 11 (described later). Peripheral circuits such as the vertical drive unit 112, the column signal processing unit 113, the horizontal drive unit 114, the system control unit 115, the signal processing unit 118, and the data storing unit 119 are further formed on the semiconductor substrate 11, identically to the pixel array unit 111, for example.

The pixel array unit 111 has a plurality of sensor pixels 110 each including a photoelectric conversion unit PD (described later) that generates and accumulates electric charges in accordance with an amount of light entered from an object. The sensor pixels 110 are respectively disposed in horizontal directions on a paper face and vertical directions on the paper face, as illustrated in FIG. 1. The horizontal directions on the paper face in FIG. 1 are also referred to as row directions, and the vertical directions on the paper face in FIG. 1 are also referred to as column directions. In the pixel array unit 111, each of the pixel drive lines 116 is wired in the row directions per a pixel row including a plurality of the sensor pixels 110 disposed in a line in the row directions. In the pixel array unit 111, each of the vertical signal lines 117 is also wired in the column directions per a pixel column including a plurality of the sensor pixels 110 disposed in a line in the column directions.

The vertical drive unit 112 includes shift resistors and address decoders, for example. The vertical drive unit 112 supplies signals to the plurality of sensor pixels 110, respectively, via a plurality of the pixel drive lines 116 to drive all the plurality of sensor pixels 110 simultaneously in the pixel array unit 111 or to drive the plurality of sensor pixels 110 in a unit of pixel row.

The vertical drive unit 112 includes, for example, two scan systems that are a reading scan system and a sweeping-out scan system. The reading scan system performs selective scanning sequentially on unit pixels in the pixel array unit 111 in a unit of row to read signals from the unit pixels. The sweeping-out scan system performs sweeping-out scanning on rows to be read, for which reading scanning is performed by the reading scan system, antecedent to the reading scanning by a period of time corresponding to a shutter speed.

Through the sweeping-out scanning performed by the sweeping-out scan system, unnecessary electric charges are swept out from the photoelectric conversion units PD in the unit pixels in the rows to be read. This operation is called resetting. Then, a so-called electronic shutter operation is performed through sweeping out of unnecessary electric charges, that is, the resetting, performed by the sweeping-out scan system. Note herein that the electronic shutter operation refers to an operation of discarding photo-electric charges in the photoelectric conversion units PD, and of newly starting exposure, that is, of newly starting accumulation of photo-electric charges.

A signal read through a reading operation by the reading scan system corresponds to an amount of light entered through the reading operation performed immediately before or at the time of and after the electronic shutter operation. A period of time from a reading timing of a reading operation performed immediately before or a sweeping-out timing of an electronic shutter operation to a reading timing of a reading operation performed at this time corresponds to an accumulation time for photo-electric charges in a unit pixel, and is referred to as an exposure time.

The signals outputted from each of the unit pixels in the pixel rows, which have undergone the selective scanning by the vertical drive unit 112, are respectively supplied to the column signal processing unit 113 via each of the vertical signal lines 117. The column signal processing unit 113 performs predetermined signal processing on the signals outputted via each of the vertical signal lines 117 from each of the unit pixels in a selected row, per each of the pixel columns in the pixel array unit 111, and temporarily retains pixel signals having undergone the signal processing.

Specifically, the column signal processing unit 113 includes shift resistors and address decoders, performs noise removal processing, correlation double sampling processing, and analog-to-digital (A/D) conversion processing through which analog pixel signals undergo A/D conversion, and generates digital pixel signals, for example. The column signal processing unit 113 supplies the generated pixel signals to the signal processing unit 118.

The horizontal drive unit 114 includes shift resistors and address decoders, for example, to sequentially select each of unit circuits, which correspond to the pixel columns, in the column signal processing unit 113. Through selective scanning performed by the horizontal drive unit 114, pixel signals having undergone signal processing per unit circuit in the column signal processing unit 113 are sequentially outputted to the signal processing unit 118.

The system control unit 115 includes a timing generator that generates various timing signals, for example. The system control unit 115 is one that performs driving control on the vertical drive unit 112, the column signal processing unit 113, and the horizontal drive unit 114 on the basis of timing signals generated by the timing generator.

The signal processing unit 118 is one that causes the data storing unit 119 to temporarily store data as necessary, performs signal processing such as computation processing on pixel signals supplied from the column signal processing unit 113, and outputs an image signal including the pixel signals.

To allow the signal processing unit 118 to perform signal processing, the data storing unit 119 temporarily stores data necessary for the signal processing.

### [Configuration of Sensor Pixel 110]

### (Circuit Configuration Example)

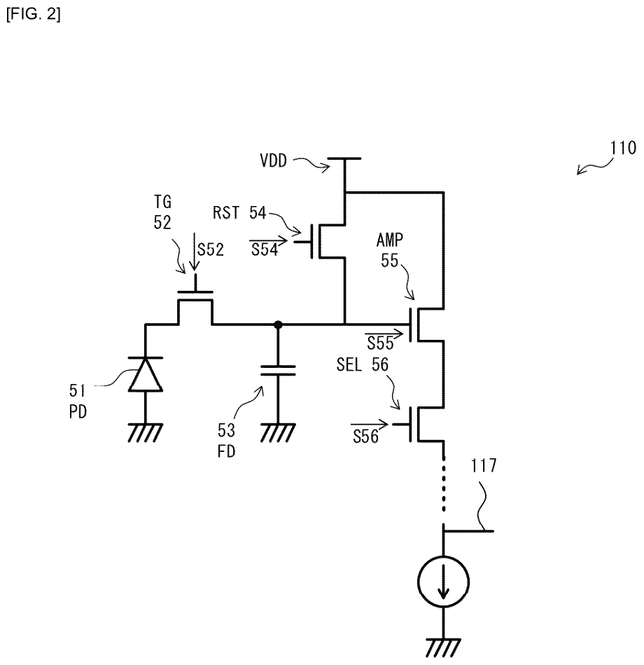

Next, a circuit configuration example of each of the sensor pixels 110 provided in the pixel array unit 111 illustrated in FIG. 1 will now be described with reference to FIG. 2. FIG. 2 illustrates the circuit configuration example of one sensor pixel 110 among the plurality of sensor pixels 110 configuring the pixel array unit 111.

In the example illustrated in FIG. 2, the sensor pixels 110 in the pixel array unit 111 each include a photoelectric conversion unit (PD) 51, a transfer transistor (TG) 52, an electric charge voltage conversion unit (FD) 53, a resetting transistor (RST) 54, an amplifier transistor (AMP) 55, and a selection transistor (SEL) 56.

In this example, the TG 52, the RST 54, the AMP 55, and the SEL 56 are all N-type MOS transistors. The vertical drive unit 112 and the horizontal drive unit 114 cause drive signals S52, S54, S55, and S56 to be respectively supplied to gate electrodes of the TG 52, the RST 54, the AMP 55, and the SEL 56 on the basis of driving control performed by the system control unit 115. The drive signals S52, S54, S55, and S56 are pulse signals where a high level state represents an active state (an on state) and a low level state represents an inactive state (an off state). Note that turning a drive signal into the active state will also be hereinafter referred to as turning on of the drive signal, and turning the drive signal into the inactive state will also be hereinafter referred to as turning off of the drive signal.

The PD 51 is a photoelectric conversion device including a photo diode having a PN junction, for example, and is configured to receive light from an object, performs photoelectric conversion on the received light, generates electric charges in accordance with an amount of the light received, and accumulates the generated electric charges.

The TG 52 is coupled between the PD 51 and the FD 53, and is configured to transfer the electric charges accumulated in the PD 51 to the FD 53 in accordance with the drive signal S52 applied to the gate electrode of the TG 52.

The RST 54 has a drain coupled to a power supply VDD and a source coupled to the FD 53. The RST 54 initializes, that is, resets the FD 53 in accordance with the drive signal S54 applied to its gate electrode. As a drive signal S58 reaches the on state, and a RST 58 is turned on, for example, an electric potential in the FD 53 is reset to a voltage level in the power supply VDD. That is, the FD 53 is initialized.

The FD 53 serves as a floating diffusion region where electric charges transferred from the PD 51 via the TG 52 are converted into and outputted as electric signals (for example, voltage signals). The FD 53 is coupled with the RST 54, and coupled with a corresponding one of the vertical signal lines 117 via the AMP 55 and the SEL 56.

### (Plan Configuration Example of Pixel Array Unit 111)

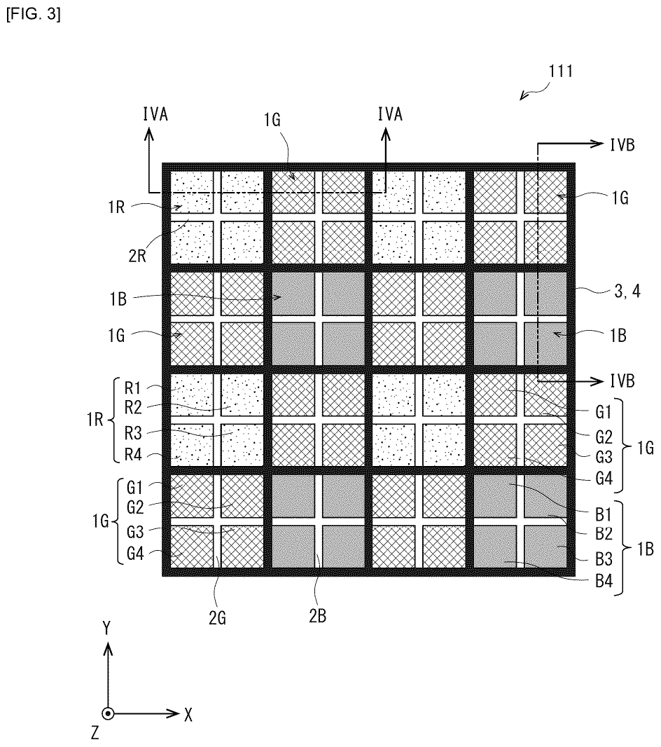

Next, a plan configuration example of the pixel array unit 111 illustrated in FIG. 1 will now be described with reference to FIG. 3. FIG. 3 is a schematic plan view illustrating a plan configuration example of a portion of the pixel array unit 111. The pixel array unit 111 includes pluralities of pixel groups disposed in a matrix on the semiconductor substrate 11, for example. The pluralities of pixel groups include a plurality of red pixel groups 1R, a plurality of green pixel groups 1G, and a plurality of blue pixel groups 1B, as illustrated in FIG. 3, for example. The red pixel groups 1R detect red light. The green pixel groups 1G detect green light. The blue pixel groups 1B detect blue light. In the example illustrated in FIG. 3, the red pixel groups 1R, the green pixel groups 1G, and the blue pixel groups 1B form a so-called Bayer layout. Note that the pluralities of pixel groups according to the present disclosure are not limited to ones that include the red pixel groups 1R, the green pixel groups 1G, and the blue pixel groups 1B, but may include pixel groups of other colors. Furthermore, the layout of the pluralities of pixel groups according to the present disclosure is not limited to the Bayer layout illustrated in FIG. 3, but may be another layout.

The plurality of red pixel groups 1R each includes a plurality of red pixels R disposed in a two dimensional array of m by m in X-axis directions and Y-axis directions (m is a natural number of two or greater). In FIG. 3, a case where m=2 is exemplified. In the present embodiment, it is described a case where m=2. Therefore, the plurality of red pixel groups 1R each includes four red pixels R1 to R4 in a square array of two columns×two rows. Similarly, the plurality of green pixel groups 1G each includes a plurality of green pixels G disposed in a two dimensional array of m by m in the X-axis directions and the Y-axis directions, that is, has four green pixels G1 to G4 disposed in a square array of two columns×two rows, as illustrated in FIG. 3, for example. Similarly, the plurality of blue pixel groups 1B each includes a plurality of blue pixels B disposed in a two dimensional array of m by m in the X-axis directions and the Y-axis directions, that is, has four blue pixels B1 to B4 in a square array of two columns×two rows, as illustrated in FIG. 3, for example. Note that the red pixels R, the green pixels G, and the blue pixels G respectively correspond to the sensor pixels 110 described in FIGS. 1 and 2.

### (Cross-Sectional Configuration Example of Pixel Array Unit 111)

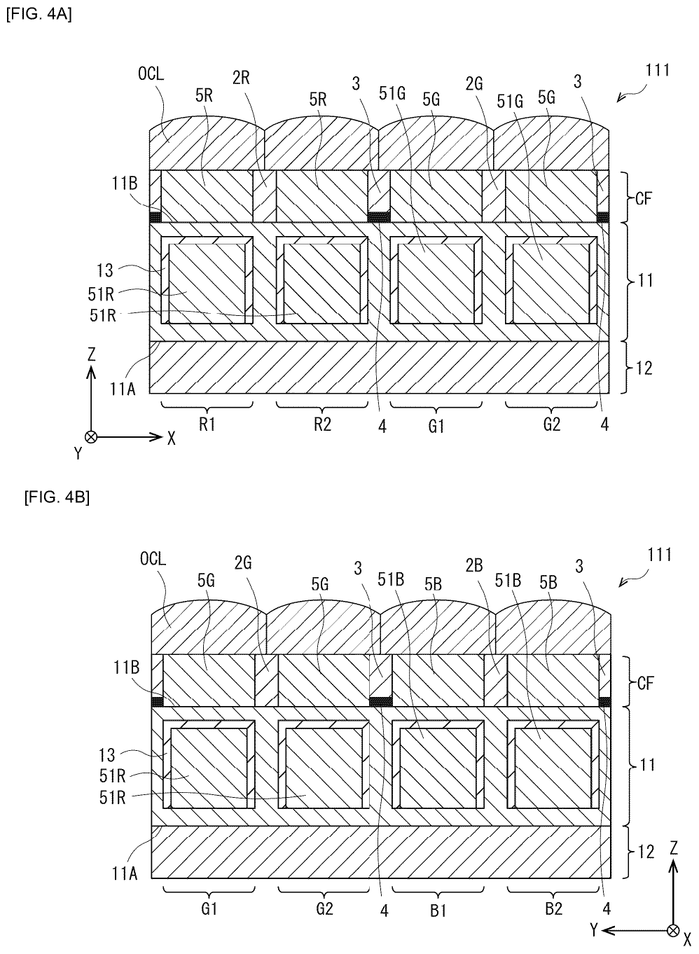

Next, a cross-sectional configuration example of the pixel array unit 111 illustrated in FIG. 1 will now be described with reference to FIGS. 4A and 4B. FIG. 4A is a cross-sectional view illustrating a configuration example of a cross section passing through one of the red pixel groups 1R and one of the green pixel groups 1G, which lie adjacent to each other in the X-axis directions. Specifically, the cross section illustrated in FIG. 4A corresponds to a cross section expanding in arrow-view directions extending along an IVA-IVA cutting line illustrated in FIG. 3. FIG. 4B is a cross-sectional view illustrating a configuration example of a cross section passing through one of the green pixel groups 1G and one of the blue pixel groups 1B, which lie adjacent to each other in the Y-axis directions. Specifically, the cross section illustrated in FIG. 4B corresponds to a cross section expanding in arrow-view directions extending along an IVB-IVB cutting line illustrated in FIG. 3. Note that the red pixels R, the green pixels G, and the blue pixels B have configurations substantially identical to each other, excluding that colors of color filters 5 differ from each other.

As illustrated in FIGS. 4A and 4B, the sensor pixels 110, that is, the red pixels R forming the red pixel groups 1R, the green pixels G forming the green pixel groups 1G, and the blue pixels B forming the blue pixel groups 1B, all respectively share the semiconductor substrate 11 and a wiring layer 12, and all respectively have the color filters 5, and on-chip lenses OCL that receive ambient light.

The semiconductor substrate 11 is a single crystal silicon substrate, for example. The semiconductor substrate 11 has a back surface 11B, and a front surface 11A lying on an opposite side to the back surface 11B. The color filters 5 and the on-chip lenses OCL are sequentially laminated with each other on the back surface 11B, respectively. The back surface 11B serves as a light-receiving surface that receives light that has passed through the on-chip lenses OCL and the color filters 5 sequentially from an object.

The semiconductor substrate 11 is provided with the photoelectric conversion units 51. The semiconductor substrate 11 may be further provided with fixed electric charge films 13 to cover the PDs 51, respectively. The fixed electric charge films 13 have negative fixed electric charges to suppress occurrence of a dark current due to an interface level at the light-receiving surface, that is, the back surface 11B of the semiconductor substrate 11. Due to electric fields that the fixed electric charge films 13 induce, respectively, hole accumulation layers are formed at positions adjacent to the back surface 11B of the semiconductor substrate 11, respectively. The hole accumulation layers suppress occurrence of electrons from the back surface 11B. Note that, in FIGS. 4A and 4B, red photoelectric conversion units 51R included in the red pixels R, green photoelectric conversion units 51G included in the green pixels G, and blue photoelectric conversion units 51B included in the blue pixels B are respectively illustrated in a differentiated manner. In the present application, there may be a case where the red photoelectric conversion units 51R, the green photoelectric conversion units 51G, and the blue photoelectric conversion units 51B are collectively and simply referred to as the photoelectric conversion units 51.

The color filters 5 are provided on the back surface 11B of the semiconductor substrate 11. Other films including reflection preventions film and planarizing films, for example, may be respectively provided between the color filters 5 and the fixed electric charge films 13. Note that, as illustrated in FIGS. 4A and 4B, the red pixels R are respectively provided with red color filters 5R in a one-by-one manner. The green pixels G are respectively provided with green color filters 5G in a one-by-one manner. The blue pixels B are respectively provided with blue color filters 5B in a one-by-one manner. The red color filters 5R mainly allow red color to pass through. The green color filters 5G mainly allow green color to pass through. The blue color filters 5B mainly allow blue color to pass through. In the present application, there may be a case where the red color filters 5R, the green color filters 5G, and the blue color filters 5B are collectively and simply referred to as the color filters 5.

The on-chip lenses OCL are positioned on opposite sides to the fixed electric charge films 13, when seen from the color filters 5, respectively, and are provided to be in contact with the color filters 5, respectively.

The wiring layer 12 is provided to cover the front surface 11A of the semiconductor substrate 11, and includes the TGs 52, for example, configuring, respectively, pixel circuits in the sensor pixels 110 illustrated in FIG. 2.

As illustrated in FIGS. 3, 4A, and 4B, the pixel array unit 111 further includes red inter-pixel wall members 2R, green inter-pixel wall members 2G, and blue inter-pixel wall members 2B. Specifically, the red inter-pixel wall members 2R are each provided in a gap among the four red pixels R1 to R4 in each of the red pixel groups 1R to separate the four red pixels R1 to R4 from each other. Similarly, the green inter-pixel wall members 2G are each provided in a gap among the four green pixels G1 to G4 in each of the green pixel groups 1G to separate the four green pixels G1 to G4 from each other. Similarly, the blue inter-pixel wall members 2B are each provided in a gap among the four blue pixels B1 to B4 in each of the blue pixel groups 1B to separate the four blue pixels B1 to B4 from each other.

More specifically, the red inter-pixel wall members 2R are each positioned in a gap among the four red color filters 5R included in each of the red pixel groups 1R. The red inter-pixel wall members 2R each have a refractive index lower than a refractive index of each of the red color filters 5R. Similarly, the green inter-pixel wall members 2G are each positioned in a gap among the four green color filters 5G included in each of the green pixel groups 1G. The green inter-pixel wall members 2G each have a refractive index lower than a refractive index of each of the green color filters 5G. The blue inter-pixel wall members 2B are each positioned in a gap among the four blue color filters 5B included in each of the blue pixel groups 1B. The blue inter-pixel wall members 2B each have a refractive index lower than a refractive index of each of the blue color filters 5B. The red inter-pixel wall members 2R, the green inter-pixel wall members 2G, and the blue inter-pixel wall members 2B may each include, for example, silicon nitride (SiN), silicon oxide (SiO₂), or a resin material, or may each have a void.

The pixel array unit 111 further includes an inter-different color pixel wall member 3 and an inter-pixel light shielding film 4. The inter-different color pixel wall member 3 and the inter-pixel light shielding film 4 are positioned in a gap among the red pixel groups 1R, the green pixel groups 1G, and the blue pixel groups 1B, respectively. The inter-different color pixel wall member 3 and the inter-pixel light shielding film 4 are laminated with each other in Z-axis directions. The inter-different color pixel wall member 3 may have, for example, a refractive index lower than the refractive index of each of the red color filters 5R, the refractive index of each of the green color filters 5G, and the refractive index of each of the blue color filters 5B. The inter-pixel light shielding film 4 suppresses transmission of light entering the pixel array unit 111. The inter-pixel light shielding film 4 includes, for example, a material containing at least one type of metal of or an oxide of one type of metal of titanium (Ti), tungsten (W), copper (Cu), or aluminum (Al). The inter-pixel light shielding film 4 may be provided in an identical layer to a color filter layer CF including the color filters 5, or may be provided between the color filter layer CF and the PDs 51 in the semiconductor substrate 11, in the Z-axis directions.

### [Workings and Effects of Solid-State Imaging Device 101]

In the solid-state imaging device 101 according to the present embodiment, as described above, the red inter-pixel wall members 2R are each positioned in a gap among a plurality of the red color filters 5R, the green inter-pixel wall members 2G are each positioned in a gap among a plurality of the green color filters 5G, and the blue inter-pixel wall members 2B are each positioned in a gap among a plurality of the blue color filters 5B. Note herein that the refractive index of each of the red inter-pixel wall members 2R is lower than the refractive index of each of the red color filters 5R, the refractive index of each of the green inter-pixel wall members 2G is lower than the refractive index of each of the green color filters 5G, and the refractive index of each of the blue inter-pixel wall members 2B is lower than the refractive index of each of the blue color filters 5B. Therefore, incident light that has once passed through the on-chip lenses OCL and has entered the red color filters 5R is reflected at an interface between each of the red color filters 5R and each of the red inter-pixel wall members 2R, and easily enters desired ones of the red photoelectric conversion units 51R. That is, incident light that has entered the red color filters 5R becomes less likely to leak from a side end face of each of the red color filters 5R to outside. Therefore, in the red pixels R, light passing through the red color filters 5R efficiently enters the red photoelectric conversion units 51R. Thereby, sensitivity of each of the red pixels R is improved.

Similarly, incident light that has once passed through the on-chip lenses OCL and has entered the green color filters 5G is reflected at an interface between each of the green color filters 5G and each of the green inter-pixel wall members 2G, and easily enters desired ones of the green photoelectric conversion units 51G. That is, incident light that has entered the green color filters 5G becomes less likely to leak from a side end face of each of the green color filters 5G to outside. Therefore, in the green pixels G, light passing through the green color filters 5G efficiently enters the green photoelectric conversion units 51G. Thereby, sensitivity of each of the green pixels G is improved.

Similarly, incident light that has once passed through the on-chip lenses OCL and has entered the blue color filters 5B is reflected at an interface between each of the blue color filters 5B and each of the blue inter-pixel wall members 2B, and easily enters desired ones of the blue photoelectric conversion units 51B. That is, incident light that has entered the blue color filters 5B becomes less likely to leak from a side end face of each of the blue color filters 5B to outside. Therefore, in the blue pixels B, light passing through the blue color filters 5B efficiently enters the blue photoelectric conversion units 51B. Thereby, sensitivity of each of the blue pixels B is improved.

Furthermore, in the pixel array unit 111 in the solid-state imaging device 101, the inter-different color pixel wall member 3 is provided among pixels that differ from each other in color. Allowing the inter-different color pixel wall member 3 to have the refractive index lower than the refractive index of each of the red color filters 5R, the refractive index of each of the green color filters 5G, and the refractive index of each of the blue color filters 5B makes it possible to further improve the sensitivity of each of the red pixels R, the sensitivity of each of the green pixels G, and the sensitivity of each of the blue pixels B. One reason of this improvement is that, for example, incident light that has once entered the red color filters 5R in the red pixels R is reflected at the interface between each of the red color filters 5R and the inter-different color pixel wall member 3, allowing the incident light to easily enter desired ones of the red photoelectric conversion units 51R. The same applies to the green pixels G and the blue pixels B.

Furthermore, in the pixel array unit 111 in the solid-state imaging device 101, the inter-pixel light shielding film 4 is provided among the pixels that differ from each other in color, suppressing transmission of incident light entering the pixel array unit 111. For example, the inter-pixel light shielding film 4 is provided in a gap between each of the red pixels R and each of the green pixels G. Therefore, even if a small amount of red light that has passed through each of the red color filters 5R or a small amount of green light that has passed through each of the green color filters 5G enters an inside of the inter-different color pixel wall member 3, and becomes leaked light, for example, the inter-pixel light shielding film 4 shields the leaked light. Therefore, it is possible to prevent leaked light, which enters from a gap among the pixels that differ from each other in color, from entering each of the photoelectric conversion units 51. That is, red light entered from each of the red pixels R becomes less likely to leak to each of the green pixels G, and green light entered from each of the green pixels G becomes less likely to leak to each of the red pixels R. Thereby, it is further possible to suppress occurrence of mixing of colors in the solid-state imaging device 101.

With the solid-state imaging device 101 according to the present embodiment, it is possible to suppress mixing of colors, to efficiently take up incident light, and to improve the sensitivity of the pixel array unit, as described above. Therefore, the solid-state imaging device 101 makes it possible to achieve a reduction in size in the in-plane directions without sacrificing its operation capability.

### 2. Modification Examples to One Embodiment

(2.1)

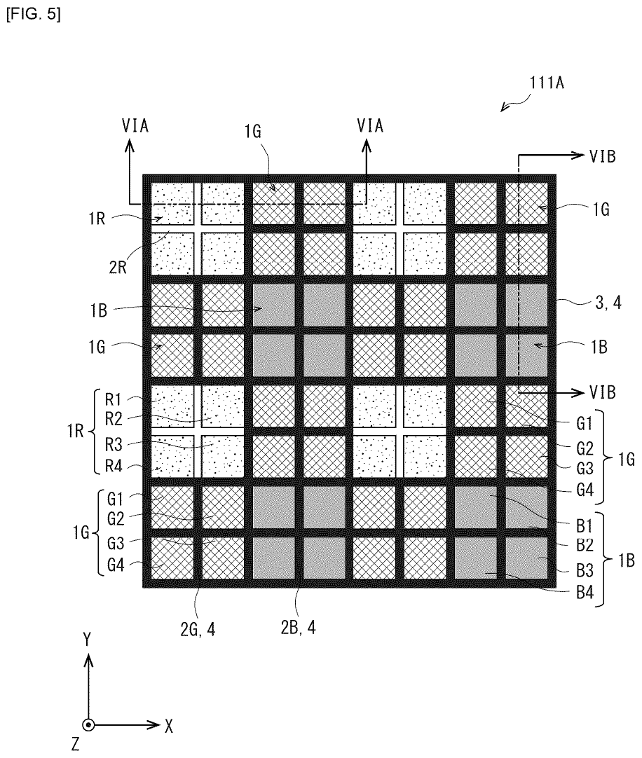

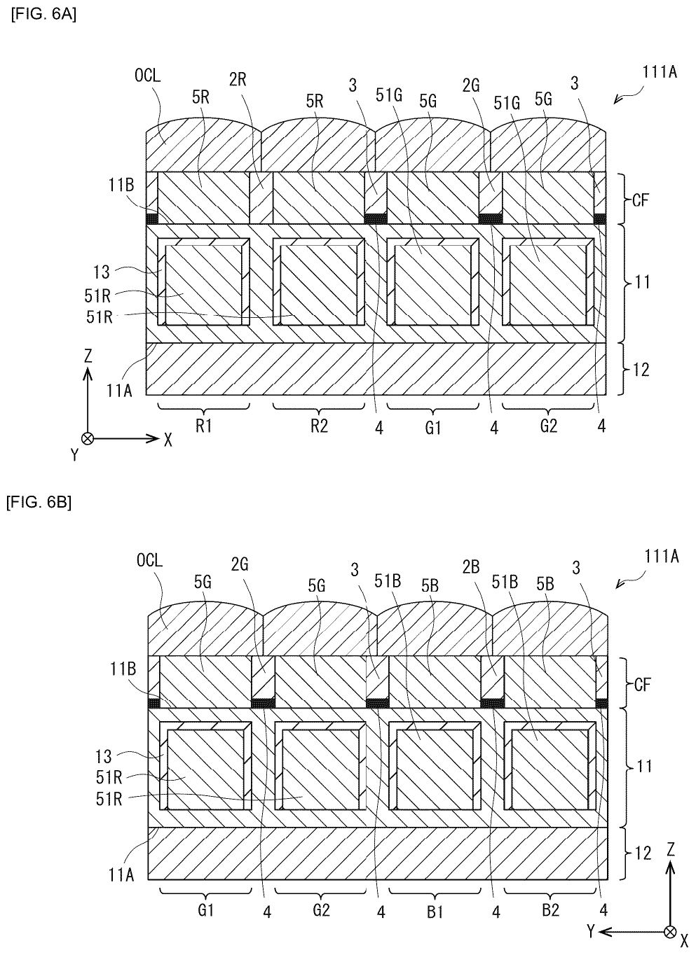

FIG. 5 is a plan view schematically illustrating a configuration example of a portion of a pixel array unit 111A serving as a first modification example to the one embodiment of the present disclosure. FIG. 5 corresponds to FIG. 3 illustrating the pixel array unit 111 according to the embodiment described above. Furthermore, FIGS. 6A and 6B each illustrate a cross-sectional configuration example of the pixel array unit 111A illustrated in FIG. 5. FIG. 6A corresponds to a cross section expanding in arrow-view directions extending along a VIA-VIA cutting line illustrated in FIG. 5. FIG. 6B corresponds to a cross section expanding in arrow-view directions extending along a VIB-VIB cutting line illustrated in FIG. 5. In the pixel array unit 111 illustrated in FIG. 3, the inter-pixel light shielding film 4 has been provided solely around each of the red pixel groups 1R, each of the green pixel groups 1G, and each of the blue pixel groups 1B. In the pixel array unit 111A illustrated in FIG. 5 and other drawings, instead, the inter-pixel light shielding film 4 is further provided inside each of the green pixel groups 1G and inside each of the blue pixel groups 1B.

Specifically, the inter-pixel light shielding film 4 is provided under the green inter-pixel wall members 2G, and is overlaid in the Z-axis directions with each of the green inter-pixel wall members 2G each positioned in a gap among the four green color filters 5G included in each of the green pixel groups 1G. Furthermore, the inter-pixel light shielding film 4 is provided under the blue inter-pixel wall members 2B, and is overlaid in the Z-axis directions with each of the blue inter-pixel wall members 2B each positioned in a gap among the four blue color filters 5B included in each of the blue pixel groups 1B.

In the pixel array unit 111A, it is possible to improve sensitivity with respect to red light in each of the red pixel groups 1R, and to reduce mixing of colors in the green pixel groups 1G and the blue pixel groups 1B. In general, as a size of each pixel is reduced, light having a longer wavelength is easily diffracted. That is, red light having a longer wavelength than a wavelength of blue light or a wavelength of green light is easily diffracted. Therefore, as a size of each pixel is reduced, there is a stronger tendency of increasing an amount of red light that leaks from the red color filters 5R in the red pixels R to each of the green pixels G and each of the blue pixels B. In the pixel array unit 111A serving as the first modification example, the inter-pixel light shielding film 4 is then further provided under each of the green inter-pixel wall members 2G, and the inter-pixel light shielding film 4 is then further provided under each of the blue inter-pixel wall members 2B. Such a configuration as described above makes it possible to reduce an amount of red light that leaks to the green photoelectric conversion units 51G in each of the green pixels G and to the blue photoelectric conversion units 51B in each of the blue pixels B, making it possible to further reduce mixing of red color and green color and mixing of red color and blue color.

(2.2)

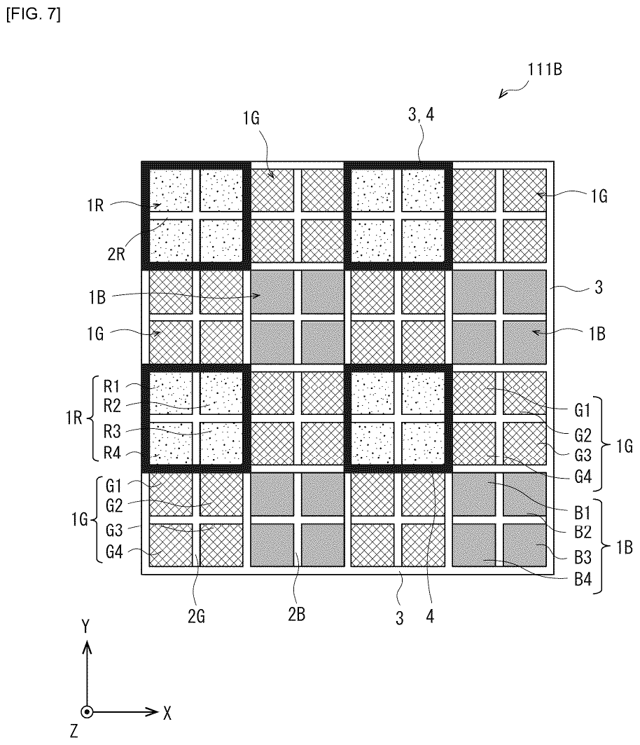

FIG. 7 is a plan view schematically illustrating a configuration example of a portion of a pixel array unit 111B serving as a second modification example to the one embodiment of the present disclosure. FIG. 7 corresponds to FIG. 3 illustrating the pixel array unit 111 according to the embodiment described above. In the pixel array unit 111 illustrated in FIG. 3, the inter-pixel light shielding film 4 has been provided around each of the red pixel groups 1R, each of the green pixel groups 1G, and each of the blue pixel groups 1B. In the pixel array unit 111B illustrated in FIG. 7, instead, the inter-pixel light shielding films 4 are each provided around each of the red pixel groups 1R, but the inter-pixel light shielding film 4 is not provided around each of the green pixel groups 1G and each of the blue pixel groups 1B.

In the pixel array unit 111B having such a configuration as described above, it is possible to suppress entry of leaked light of red light from each of the red pixel groups 1R into each of the green pixel groups 1G and each of the blue pixel groups 1B. Furthermore, it is possible to further improve the sensitivity of each of the green pixel groups 1G and each of the blue pixel groups 1B, compared with the pixel array unit 111 illustrated in FIG. 3.

(2.3)

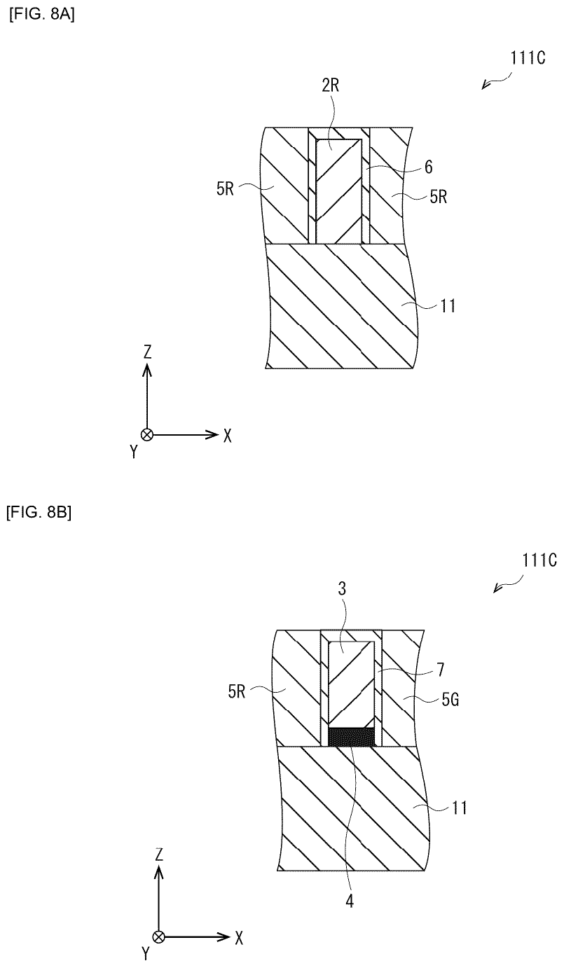

FIG. 8A is a cross-sectional view illustrating, in an enlarged manner, a configuration example of one of the red inter-pixel wall members 2R in a pixel array unit 111C and its periphery, which serves as a third modification example to the one embodiment of the present disclosure. Furthermore, FIG. 8B is a cross-sectional view illustrating, in an enlarged manner, a configuration example of the inter-different color pixel wall member 3 and the inter-pixel light shielding film 4 in the pixel array unit 111C and its periphery, which serves as the third modification example. In the pixel array unit 111C, as illustrated in FIG. 8A, at least side surfaces of each of the red inter-pixel wall members 2R are covered with a protective film 6. Although FIG. 8A exemplifies one of the red inter-pixel wall members 2R, the green inter-pixel wall members 2G and the blue inter-pixel wall members 2B may be each similarly covered with the protective film 6. Furthermore, in the pixel array unit 111C, as illustrated in FIG. 8B, at least side surfaces of the inter-different color pixel wall member 3 and at least side surfaces of the inter-pixel light shielding film 4 are covered with a protective film 7.

The protective film 6 and the protective film 7 both include an insulating material such as a silicon oxide film. However, the protective film 6 that covers each of the red inter-pixel wall members 2R may have a refractive index higher than the refractive index of each of the red inter-pixel wall members 2R and lower than the refractive index of each of the red color filters 5R. Similarly, the protective film 6 that covers each of the green inter-pixel wall members 2G may have the refractive index higher than the refractive index of each of the green inter-pixel wall members 2G and lower than the refractive index of each of the green color filters 5G. The protective film 6 that covers each of the blue inter-pixel wall members 2B may have the refractive index higher than the refractive index of each of the blue inter-pixel wall members 2B and lower than the refractive index of each of the blue color filters 5B.

The protective film 7 that covers the inter-different color pixel wall member 3 and the inter-pixel light shielding film 4 in the gap between each of the red pixel groups 1R and each of the green pixel groups 1G may have a refractive index higher than the refractive index of the inter-different color pixel wall member 3 and lower than both the refractive index of each of the red color filters 5R and the refractive index of each of the green color filters 5G. Furthermore, the protective film 7 that covers the inter-different color pixel wall member 3 and the inter-pixel light shielding film 4 in the gap between each of the red pixel groups 1R and each of the blue pixel groups 1B may have the refractive index higher than the refractive index of the inter-different color pixel wall member 3 and lower than both the refractive index of each of the red color filters 5R and the refractive index of each of the blue color filters 5B. Furthermore, the protective film 7 that covers the inter-different color pixel wall member 3 and the inter-pixel light shielding film 4 in the gap between each of the blue pixel groups 1B and each of the green pixel groups 1G may have the refractive index higher than the refractive index of the inter-different color pixel wall member 3 and lower than both the refractive index of each of the blue color filters 5B and the refractive index of each of the green color filters 5G.

### 3. Application Example to Electronic Apparatus

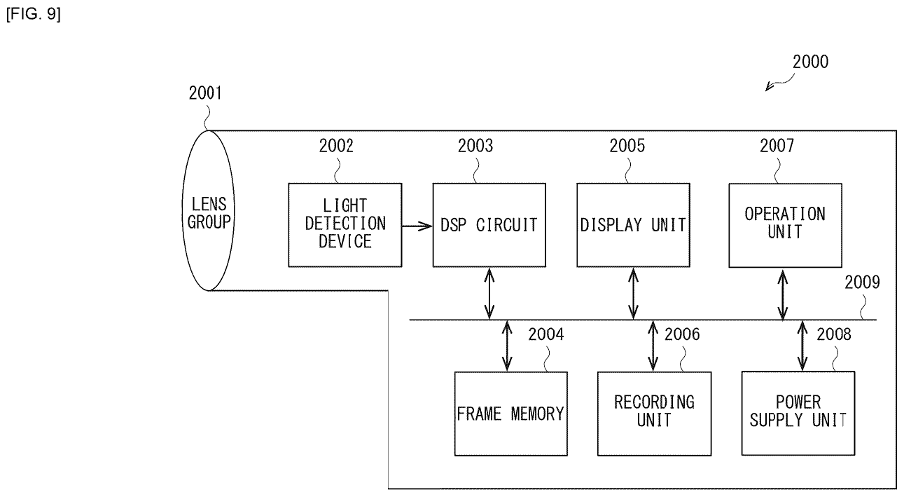

FIG. 9 is a block diagram illustrating a configuration example of a camera 2000 serving as an electronic apparatus to which the present technique is applied.

The camera 2000 includes an optical unit 2001 including a lens group, for example, an imaging device (imaging device) 2002 to which the solid-state imaging device 101 described above, for example, (hereinafter referred to as the solid-state imaging device 101, for example) is applied, and a digital signal processor (DSP) circuit 2003 serving as a camera signal processing circuit. Furthermore, the camera 2000 further includes a frame memory 2004, a display unit 2005, a recording unit 2006, a operation unit 2007, and a power supply unit 2008. The DSP circuit 2003, the frame memory 2004, the display unit 2005, the recording unit 2006, the operation unit 2007, and the power supply unit 2008 are coupled to each other via a bus line 2009.

The optical unit 2001 takes up incident light (image light) from an object, and forms an image on an imaging surface of the imaging device 2002. The imaging device 2002 converts an amount of light of the incident light that has formed the image on the imaging surface by the optical unit 2001, in a unit of pixel, into an electric signal, and outputs the converted electric signal as a pixel signal.

The display unit 2005 includes, for example, a panel type display machine such as a liquid crystal panel or an organic electro-luminescence (EL) panel type display machine, and displays a moving image or still image captured by the imaging device 2002. The recording unit 2006 causes a recording medium such as a hard disk or semiconductor memory to record the moving image or still image captured by the imaging device 2002.

The operation unit 2007 issues operation commands for various functions that the camera 2000 has, on the basis of operations performed by a user. The power supply unit 2008 appropriately supplies various power supplies serving as respective operation power supplies for the DSP circuit 2003, the frame memory 2004, the display unit 2005, the recording unit 2006, and the operation unit 2007 to those supply targets.

By using the solid-state imaging device 101, for example, described above as the imaging device 2002, it is possible to expect acquisition of a proper image, as described above.

### 4. Practical Example to Movable Body

It is possible to apply the technique of the present disclosure (the technique) to various products. For example, the technique of the present disclosure may be achieved as a machine mounted in any kinds of movable bodies including vehicles, electric vehicles, hybrid electric vehicles, motorcycles, bicycles, personal mobilities, airplanes, drones, ships and vessels, and robots.

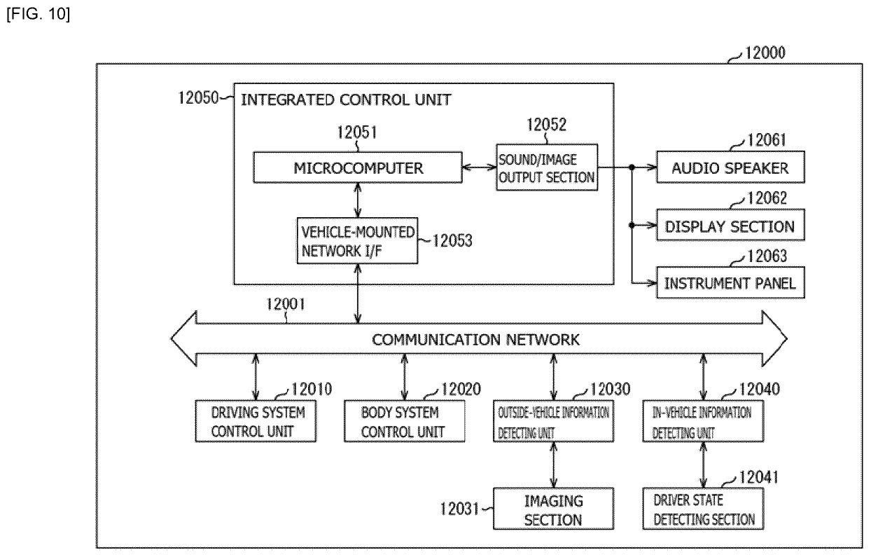

FIG. 10 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 10, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 10, an audio speaker 12061, a display section 12062, and an instrument panel 12063 are illustrated as the output device. The display section 12062 may, for example, include at least one of an on-board display and a head-up display.

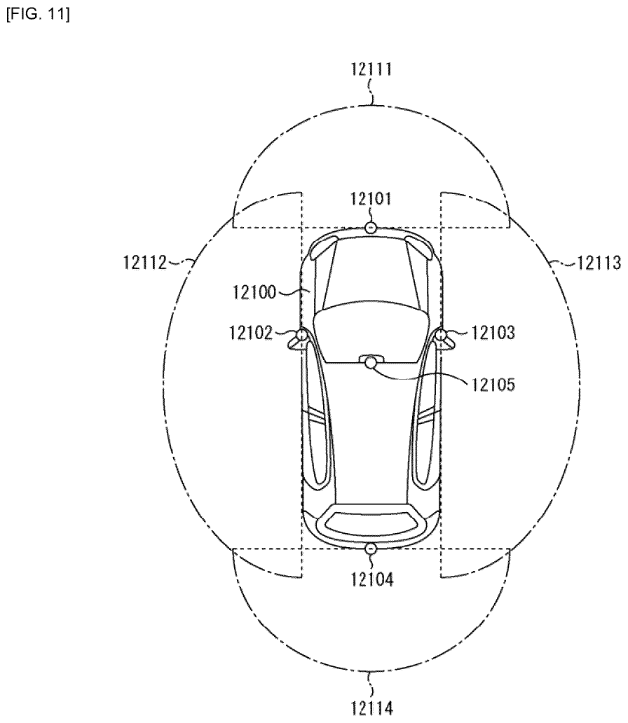

FIG. 11 is a diagram depicting an example of the installation position of the imaging section 12031.

In FIG. 11, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 11 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The example of the vehicle control system to which it is possible to apply the technique of the present disclosure has been described. The technique of the present disclosure may be applied to the imaging unit 12031, among the components described above. Specifically, it is possible to apply the solid-state imaging device 101, for example, illustrated in FIG. 1 and other drawings to the imaging unit 12031. With the imaging unit 12031 applied with the technique according to the present disclosure, it is possible to expect superior operation of the vehicle control system.

### 5. Practical Example to Endoscopic Surgery System

It is possible to apply the technique of the present disclosure (the technique) to various products. For example, the technique according to the present disclosure may be applied to an endoscopic surgery system.

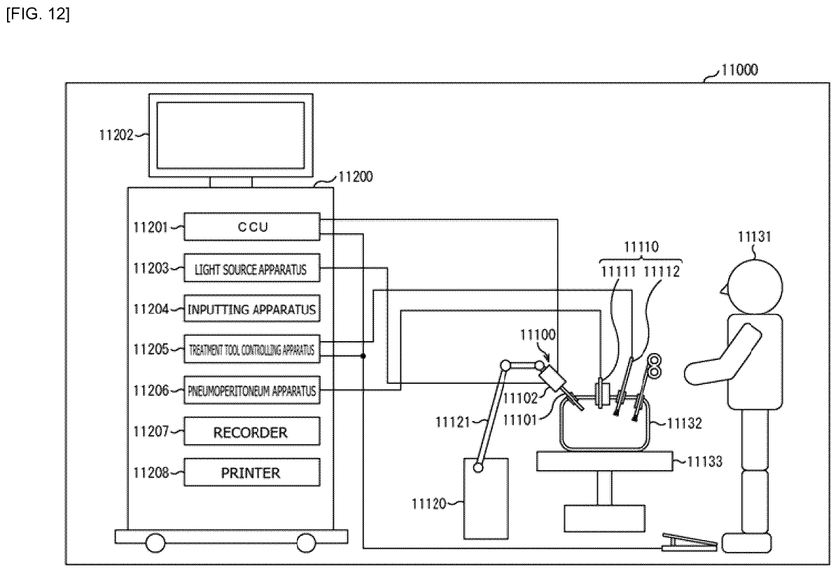

FIG. 12 is a view depicting an example of a schematic configuration of an endoscopic surgery system to which the technology according to an embodiment of the present disclosure (present technology) can be applied.

In FIG. 12, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

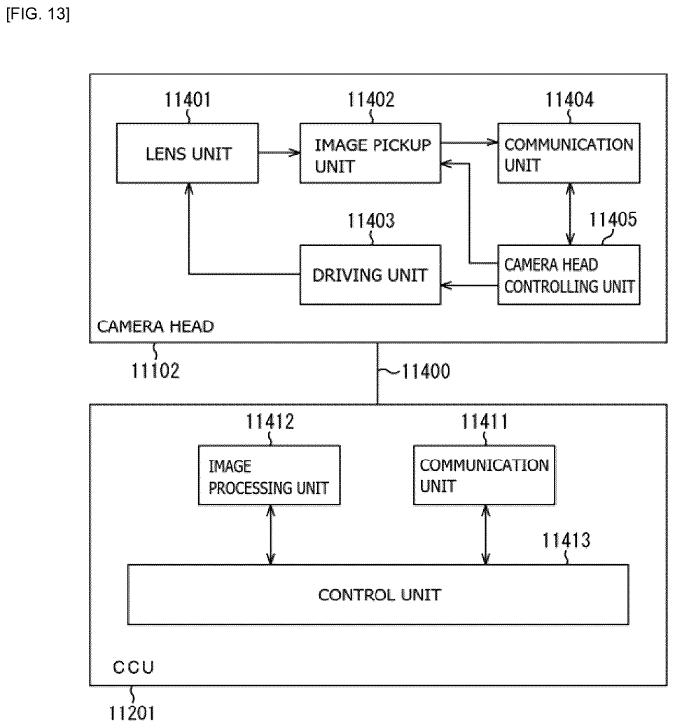

FIG. 13 is a block diagram depicting an example of a functional configuration of the camera head 11102 and the CCU 11201 depicted in FIG. 12.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

The example of the endoscopic surgery system to which it is possible to apply the technique according to the present disclosure has been described. The technique according to the present disclosure may be advantageously applied to the imaging unit 11402 provided in the camera head 11102 of the endoscope 11100, among the components described above, for example. With the imaging unit 11402 applied with the technique according to the present disclosure, it is possible to make the imaging unit 11402 highly sensitive, making it possible to provide the endoscope 11100 with a high definition property.

### 6. Other Modification Examples

Although the present disclosure has been described with reference to the embodiment and the modification examples, the present disclosure is not limited to the embodiment and the modification examples described above, but may be modified in a wide variety of ways. In the embodiment described above, it has been described an example case where one pixel group includes four pixels disposed in a square array of two columns×two rows, that is, an example case where m=2, for example. However, m may be 3 or greater in the present disclosure.

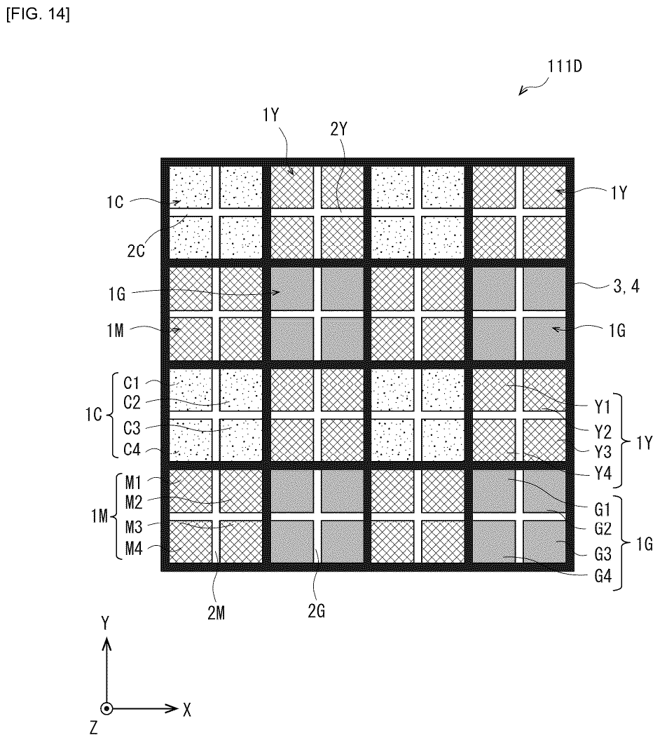

Furthermore, it has been exemplified one that detects and acquires, as an image, distribution of amounts of light of red light, green light, and blue light, as the imaging device according to the present disclosure. However, the present disclosure is not limited to the example. In the imaging device according to the present disclosure, it is possible to adopt an array of pixel groups represented by a pixel array unit 111D serving as a fourth modification example illustrated in FIG. 14, for example. Specifically, the pixel array unit 111D may be one where yellow pixel groups 1Y that acquire yellow light, cyan pixel groups 1C that acquire cyan light, magenta pixel groups 1M that acquire magenta light, and green pixel groups 1G that acquire green light are each disposed in a square array of two columns×two rows. The inter-different color pixel wall member 3 and the inter-pixel light shielding film 4 are provided around each of the yellow pixel groups 1Y, the cyan pixel groups 1C, the magenta pixel groups 1M, and the green pixel groups 1G. The yellow pixel groups 1Y each include four yellow pixels Y1 to Y4 disposed in a square array of two columns×two rows. A yellow inter-pixel wall member 2Y is provided in a gap among the four yellow pixels Y1 to Y4. A cyan inter-pixel wall member 2C is provided in a gap among four cyan pixels C1 to C4. A magenta inter-pixel wall member 2M is provided in a gap among four magenta pixels M1 to M4. A green inter-pixel wall member 2G is provided in a gap among four green pixels G1 to G4. Therefore, even in the pixel array unit 111D illustrated in FIG. 14, it is possible to expect effects similar to the effects of the pixel array unit 111 illustrated in FIG. 3.

Furthermore, in the imaging device according to the present disclosure, the inter-pixel light shielding film 4 may extend downward than a lower surface of each of the color filters 5, similar to a pixel array unit 111E serving as a fifth modification example illustrated in FIG. 15, for example. Note that, in the pixel array unit 111E, an insulating layer 14 is provided between the semiconductor substrate 11 and the color filter layer CF. The inter-pixel light shielding film 4 is partially buried in the insulating layer 14.

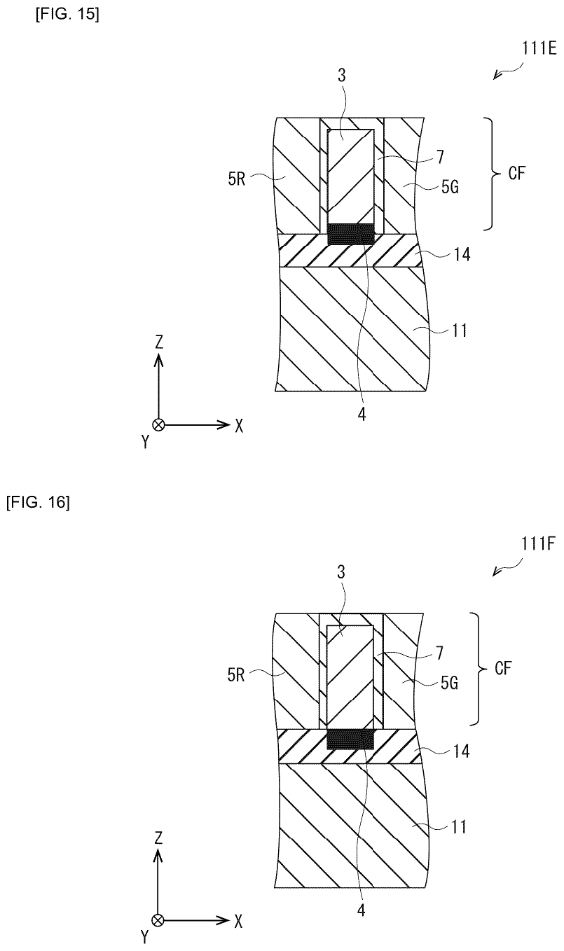

Furthermore, in the imaging device according to the present disclosure, the inter-pixel light shielding film 4 may be solely provided below the lower surface of each of the color filters 5, similar to a pixel array unit 111F serving as a sixth modification example illustrated in FIG. 16, for example. Note that, in the pixel array unit 111F, the inter-pixel light shielding film 4 provided below the inter-different color pixel wall member 3 is fully buried in the insulating layer 14.

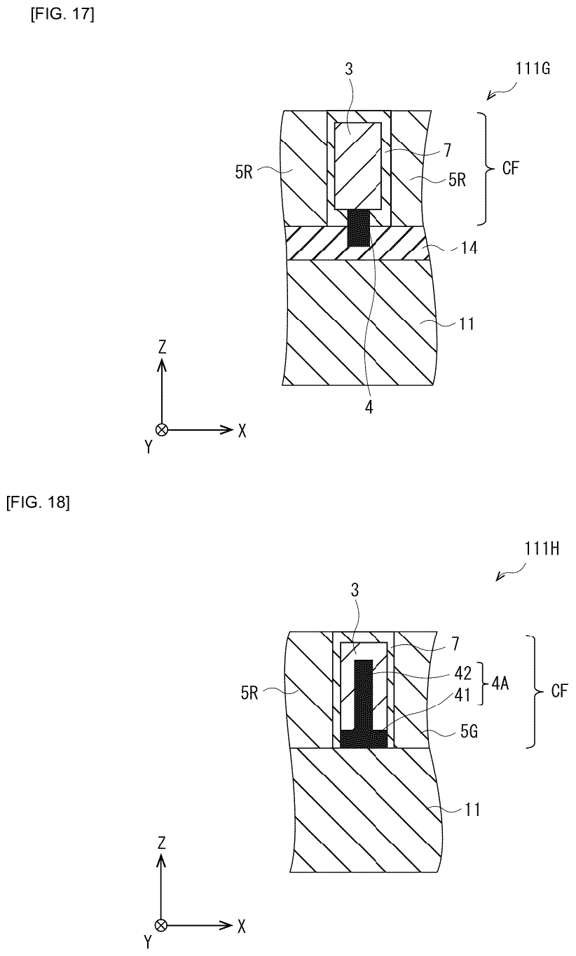

Furthermore, in the imaging device according to the present disclosure, the inter-pixel light shielding film 4 may extend downward than the lower surface of each of the color filters 5, and a width of the inter-pixel light shielding film 4 may be narrower than a width of the inter-different color pixel wall member 3, similar to a pixel array unit 111G serving as a seventh modification example illustrated in FIG. 17, for example.

Furthermore, in the imaging device according to the present disclosure, an inter-pixel light shielding film 4A may be adopted, instead of the inter-pixel light shielding film 4, similar to a pixel array unit 111H serving as an eighth modification example illustrated in FIG. 18, for example. The inter-pixel light shielding film 4A includes a base 41 and a wall 42. The base 41 has a width identical to the width of the inter-different color pixel wall member 3, and is positioned below the inter-different color pixel wall member 3, for example. The wall 42 has a width narrower than the width of the base 41. At least side surfaces of the wall 42 are covered with the inter-different color pixel wall member 3. In the pixel array unit 111H, adopting the inter-pixel light shielding film 4A makes it possible to further improve its sensitivity than that of the pixel array unit 111, and to further improve a light shielding capability of shielding leaked light.

Furthermore, in the imaging device according to the present disclosure, the width of the inter-pixel light shielding film 4 may be narrower than the width of the inter-different color pixel wall member 3, even in the pixel array unit 111 illustrated in FIG. 4A, for example. Furthermore, it is possible to appropriately select a ratio of a thickness of the inter-pixel light shielding film 4 and a thickness of the inter-different color pixel wall member 3.

With the imaging device and the electronic apparatus according to the one embodiment of the present disclosure, it is possible to suppress mixing of colors, to efficiently take up incident light, and to improve the sensitivity of the pixel array unit, as described above.

Note that the effects described in the specification are mere examples. The effects of the technique are not limited to the effects described in the specification. There may be any other effects than those described herein. Furthermore, the present technique is one that may have such configurations as described below.

(1)

An imaging device including:
a base body;
a pixel array unit including a plurality of first color pixels lying adjacent to each other and each including a first color filter and a first photoelectric conversion unit that receives first color light passed through the first color filter and performs photoelectric conversion on the first color light and a plurality of second color pixels lying adjacent to each other and each including a second color filter and a second photoelectric conversion unit that receives second color light passed through the second color filter and performs photoelectric conversion on the second color light, the plurality of first color pixels and the plurality of second color pixels being disposed on the base body;
a first inter-identical color pixel wall member positioned in a gap among a plurality of the first color filters, the first inter-identical color pixel wall member having a refractive index lower than a refractive index of the first color filter; and
an inter-pixel light shielding film positioned in a gap between the plurality of first color pixels and the plurality of second color pixels, the inter-pixel light shielding film suppressing transmission of light entering the pixel array unit.
   (2)

The imaging device according to (1) described above, in which a side surface of the first inter-identical color pixel wall member is covered with a first protective film having a refractive index higher than the refractive index of the first inter-identical color pixel wall member and lower than the refractive index of the first color filter.

(3)

The imaging device according to (1) or (2) described above, further including a first inter-different color pixel wall member positioned in a gap between the first color filter and the second color filter, the first inter-different color pixel wall member being laminated together with the light shielding film, the first inter-different color pixel wall member having a refractive index lower than both the refractive index of the first color filter and a refractive index of the second color filter.

(4)

The imaging device according to any one of (1) to (3) described above, in which a side surface of the first inter-different color pixel wall member is covered with a third protective film having a refractive index higher than a refractive index of the first inter-different color pixel wall member and lower than both the refractive index of the first color filter and a refractive index of the second color filter.

(5)

The imaging device according to any one of (1) to (4) described above, further including a second inter-identical color pixel wall member positioned in a gap among a plurality of the second color filters, the second inter-identical color pixel wall member having a refractive index lower than a refractive index of the second color filter.

(6)

The imaging device according to any one of (1) to (5) described above, in which a side surface of the second inter-identical color pixel wall member is covered with a second protective film having a refractive index higher than the refractive index of the second inter-identical color pixel wall member and lower than the refractive index of the second color filter.

(7)

The imaging device according to (1), in which
the first color pixel is a red pixel, and
the inter-pixel light shielding film is provided solely around a red pixel group including a plurality of the red pixels.
   (8)

The imaging device according to any one of (1) to (7) described above, in which the first inter-identical color pixel wall member includes SiN (silicon nitride), SiO₂ (silicon oxide), or a resin material, or has a void.

(9)

The imaging device according to any one of (1) to (8) described above, in which the inter-pixel light shielding film includes a material containing at least one of Ti (titanium), W (tungsten), Cu (copper), Al (aluminum) or oxides thereof.

(10)

The imaging device according to any one of (1) to (9) described above, in which the inter-pixel light shielding film is provided at an identical layer to a color filter layer including the first color filter and the second color filter, or provided between the first color filter and the first photoelectric conversion unit and between the second color filter and the second photoelectric conversion unit.

(11)

An electronic apparatus including an imaging device, the imaging device including:
a base body;
a pixel array unit including a plurality of first color pixels lying adjacent to each other and each including a first color filter and a first photoelectric conversion unit that receives first color light passed through the first color filter and performs photoelectric conversion on the first color light and a plurality of second color pixels lying adjacent to each other and each including a second color filter and a second photoelectric conversion unit that receives second color light passed through the second color filter and performs photoelectric conversion on the second color light, the plurality of first color pixels and the plurality of second color pixels being disposed on the base body;
a first inter-identical color pixel wall member positioned in a gap among a plurality of the first color filters, the first inter-identical color pixel wall member having a refractive index lower than a refractive index of the first color filter; and
an inter-pixel light shielding film positioned in a gap between the plurality of first color pixels and the plurality of second color pixels, the inter-pixel light shielding film suppressing transmission of light entering the pixel array unit.

The present application claims the benefit of Japanese Priority Patent Application JP 2021-147996 filed with the Japan Patent Office on Sep. 10, 2021, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. An imaging device comprising:
a base body;
a pixel array unit including a plurality of first color pixels lying adjacent to each other and each including a first color filter and a first photoelectric conversion unit that receives first color light passed through the first color filter and performs photoelectric conversion on the first color light and a plurality of second color pixels lying adjacent to each other and each including a second color filter and a second photoelectric conversion unit that receives second color light passed through the second color filter and performs photoelectric conversion on the second color light, the plurality of first color pixels and the plurality of second color pixels being disposed on the base body;
a first inter-identical color pixel wall member positioned in a gap among a plurality of the first color filters, the first inter-identical color pixel wall member having a refractive index lower than a refractive index of the first color filter; and
an inter-pixel light shielding film positioned in a gap between the plurality of first color pixels and the plurality of second color pixels, the inter-pixel light shielding film suppressing transmission of light entering the pixel array unit.

2. The imaging device according to claim 1, wherein a side surface of the first inter-identical color pixel wall member is covered with a first protective film having a refractive index higher than the refractive index of the first inter-identical color pixel wall member and lower than the refractive index of the first color filter.

3. The imaging device according to claim 1, further comprising a first inter-different color pixel wall member positioned in a gap between the first color filter and the second color filter, the first inter-different color pixel wall member being laminated together with the inter-pixel light shielding film, the first inter-different color pixel wall member having a refractive index lower than both the refractive index of the first color filter and a refractive index of the second color filter.

4. The imaging device according to claim 1, wherein a side surface of the first inter-different color pixel wall member is covered with a third protective film having a refractive index higher than a refractive index of the first inter-different color pixel wall member and lower than both the refractive index of the first color filter and a refractive index of the second color filter.

5. The imaging device according to claim 1, further comprising a second inter-identical color pixel wall member positioned in a gap among a plurality of the second color filters, the second inter-identical color pixel wall member having a refractive index lower than a refractive index of the second color filter.

6. The imaging device according to claim 5, wherein a side surface of the second inter-identical color pixel wall member is covered with a second protective film having a refractive index higher than the refractive index of the second inter-identical color pixel wall member and lower than the refractive index of the second color filter.

7. The imaging device according to claim 1, wherein
the first color pixel is a red pixel, and
the inter-pixel light shielding film is provided solely around a red pixel group including a plurality of the red pixels.

8. The imaging device according to claim 1, wherein the first inter-identical color pixel wall member includes SiN (silicon nitride), SiO₂ (silicon oxide), or a resin material, or has a void.

9. The imaging device according to claim 1, wherein the inter-pixel light shielding film includes a material containing at least one of Ti (titanium), W (tungsten), Cu (copper), Al (aluminum) or oxides thereof.

10. The imaging device according to claim 1, wherein the inter-pixel light shielding film is provided at an identical layer to a color filter layer including the first color filter and the second color filter, or provided between the first color filter and the first photoelectric conversion unit and between the second color filter and the second photoelectric conversion unit.

11. An electronic apparatus comprising an imaging device, the imaging device including:
a base body;
a pixel array unit including a plurality of first color pixels lying adjacent to each other and each including a first color filter and a first photoelectric conversion unit that receives first color light passed through the first color filter and performs photoelectric conversion on the first color light and a plurality of second color pixels lying adjacent to each other and each including a second color filter and a second photoelectric conversion unit that receives second color light passed through the second color filter and performs photoelectric conversion on the second color light, the plurality of first color pixels and the plurality of second color pixels being disposed on the base body;
a first inter-identical color pixel wall member positioned in a gap among a plurality of the first color filters, the first inter-identical color pixel wall member having a refractive index lower than a refractive index of the first color filter; and
an inter-pixel light shielding film positioned in a gap between the plurality of first color pixels and the plurality of second color pixels, the inter-pixel light shielding film suppressing transmission of light entering the pixel array unit.
